(19) United States
(12) Patent Application Publication
(10) Pub. No.: US 2023/0114872 A1
(43) Pub. Date: Apr. 13, 2023

(54) ELECTRONIC DEVICE WITH WETTABLE FLANK LEAD

(71) Applicant: Texas Instruments Incorporated, Dallas, TX (US)

(72) Inventor: Nazila Dadvand, Allen, TX (US)

(21) Appl. No.: 17/710,920

(22) Filed: Mar. 31, 2022

Related U.S. Application Data
(60) Provisional application No. 63/255,170, filed on Oct. 13, 2021.

(51) Int. Cl. H01L 23/495; H01L 21/48

(52) U.S. Cl. CPC H01L 23/49582; H01L 23/49548; H01L 23/49534; H01L 21/4821; H01L 24/48

(57) ABSTRACT

An electronic device includes a package structure and a conductive lead with a first surface and a second surface. The first surface has a first plated layer exposed outside the package structure along a first side of the package structure, and the second surface has a second plated layer exposed along the bottom side of the package structure. A method includes forming a first plated layer on a first surface of a conductive lead exposed along a bottom side of a molded structure in a panel array, performing a package separation process that separates an electronic device from the panel array, placing the bottom side of the package structure and the first plated layer on a tape layer above a conductive plate, and forming a second plated layer on the exposed second surface of the conductive lead.

### CROSS-REFERENCE TO RELATED APPLICATION

This application claims priority to and benefit of U.S. Provisional patent application Ser. No. 63/255,170, filed on Oct. 13, 2021, and titled “A Novel Method for Fabricating of Wettable Flank QFN Packages”, the contents of which are hereby fully incorporated by reference.

### BACKGROUND

Quad flat no-lead (QFN) and dual flat no-lead (DFN) packaged electronic devices have conductive leads with bottoms and sidewalls. Board level reliability (BLR) of electronic devices can be adversely affected by corrosion or degradation of the conductive metal of the lead bottom or sidewall. Wettable flank options can provide a protective coating to surface mount device lead surfaces to mitigate corrosion and lengthen shelf-life of an electronic device prior to soldering onto a host printed circuit board (PCB). Wettable flanks also facilitate automated optical inspection (AOI) of devices soldered to a PCB for determining whether a proper connection has been made on a pad under the device.

### SUMMARY

In one aspect, an electronic device includes a package structure and a conductive lead that has a first surface and a second surface. The first surface of the lead has a first plated layer exposed along the first side of the package structure, and the second surface has a second plated layer along a bottom side of the package structure.

In another aspect, a method includes performing a first plating process that forms a first plated layer on a first surface of a conductive lead exposed along a bottom side of a molded structure in a panel array of prospective electronic devices, and performing a package separation process that separates an electronic device from the panel array, with the conductive lead exposed along the bottom side of a respective package structure, and exposes a second surface of the conductive lead along a first side of the package structure. The method includes placing the bottom side of the package structure and the first plated layer on a tape layer above a conductive plate and performing a second plating process that forms a second plated layer on the exposed second surface of the conductive lead.

In a further aspect an electronic device includes a package structure and a conductive lead that has a first surface, a second surface, a first plated layer, and a second plated layer. The first surface extends along a first side of the package structure, and the second surface extends along a bottom side of the package structure. The first plated layer extends on the first and second surfaces of the conductive lead and includes cobalt boride, and the second plated layer extends on the first plated layer and includes gold.

In another aspect, a method includes performing a package separation process that separates an electronic device from a panel array, with a first surface of a conductive lead exposed along a bottom side of a respective package structure and exposes a second surface of the conductive lead along a first side of the package structure. The method includes performing a first plating process that forms a first plated layer extending on the first and second surfaces of the conductive lead and includes cobalt boride and performing a second plating process that forms a second plated layer extending on the first plated layer and includes gold.

In another aspect, an electronic device includes a package structure and a conductive lead with a first surface, a second surface, a first plated layer, and a second plated layer. The first surface extends along the first side of the package structure, and the second surface extends along the fifth side of the package structure, the first plated layer extends on the first surface of the conductive lead and includes cobalt, the second plated layer extends on the first plated layer and on the second surface of the conductive lead, and the second plated layer includes tin.

In a further aspect, a method includes performing a first plating process that forms a first plated layer including cobalt on a first surface of a conductive lead exposed along a bottom side of a molded structure in a panel array of prospective electronic devices, performing a second plating process that forms a copper layer on the first plated layer, performing a package separation process that separates an electronic device from the panel array, with the conductive lead exposed along the bottom side of a respective package structure, and exposes a second surface of the conductive lead along a first side of the package structure, and performing a third plating process that forms a second plated layer includes tin on the second surface of the conductive lead along a first side of the package structure and consumes the copper layer to form the second plated layer includes tin on the first plated layer of the first surface of the conductive lead.

### BRIEF DESCRIPTION OF THE DRAWINGS

FIG. 1 is a perspective view of an electronic device.

FIG. 1A is a bottom view of the electronic device of FIG. 1.

FIG. 1B is a partial sectional side elevation view of the electronic device of FIGS. 1 and 1A.

FIG. 2 is a flow diagram of a method of fabricating an electronic device.

FIGS. 3-13 are partial sectional side elevation views of the electronic device of FIGS. 1-1B undergoing fabrication processing according to the method of FIG. 2.

FIG. 14 is a perspective view of the electronic device of FIGS. 1 and 1A undergoing an electroplating process for sidewall plating according to the method of FIG. 2.

FIG. 15 is a perspective view of another electronic device.

FIG. 15A is a bottom view of the electronic device of FIG. 15.

FIG. 15B is a partial sectional side elevation view of the electronic device of FIGS. 15 and 15A.

FIG. 16 is a flow diagram of a method of fabricating an electronic device.

FIGS. 17-22 are partial sectional side elevation views of the electronic device of FIGS. 15-15B undergoing fabrication processing according to the method of FIG. 16.

FIG. 23 is a perspective view of another electronic device.

FIG. 23A is a bottom view of the electronic device of FIG. 23.

FIG. 23B is a partial sectional side elevation view of the electronic device of FIGS. 23 and 23A.

FIG. 24 is a flow diagram of a method of fabricating an electronic device.

FIGS. 25-31 are partial sectional side elevation views of the electronic device of FIGS. 23-23B undergoing fabrication processing according to the method of FIG. 24.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections.

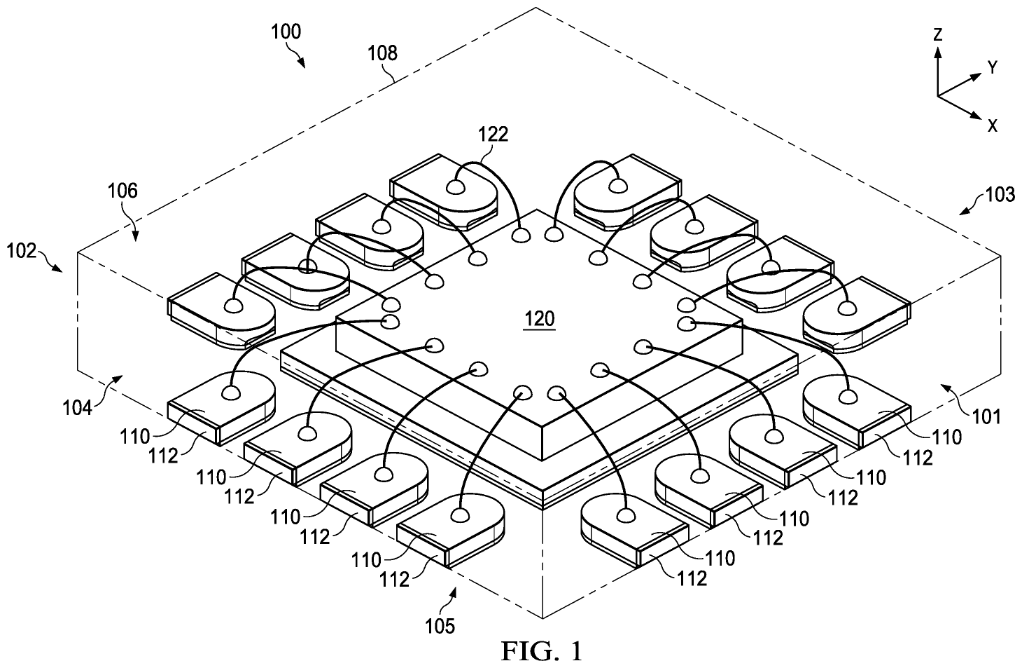

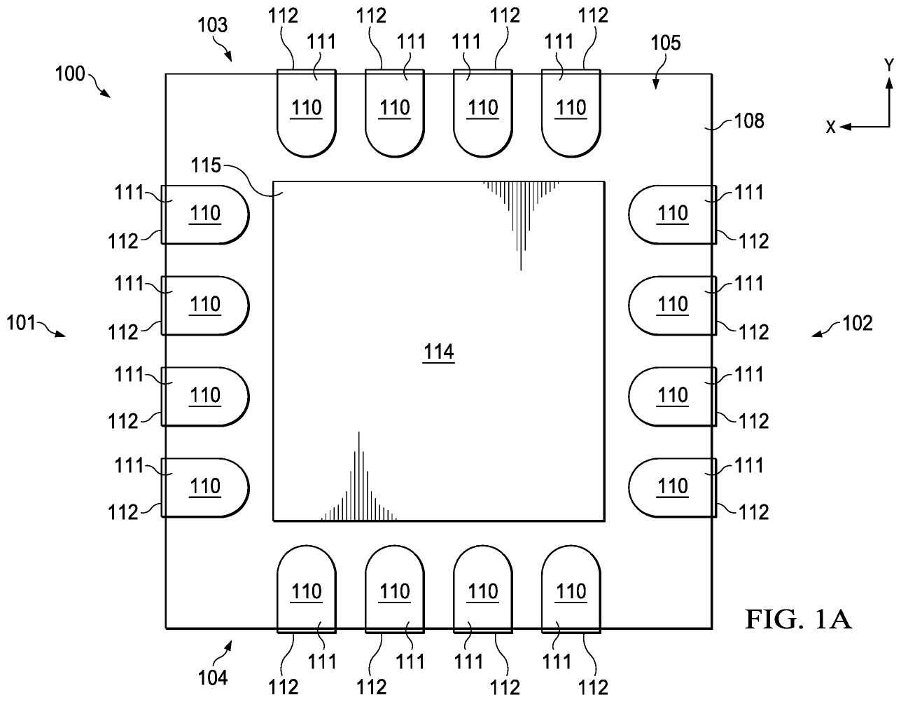

Referring initially to FIGS. 1-1B, FIG. 1 shows an electronic device 100, FIG. 1A shows a bottom view of the electronic device 100, and FIG. 1B shows a partial sectional side elevation view of a conductive lead 110 of the electronic device 100. The electronic device 100 is illustrated in an example position in a three-dimensional space with respective first, second, and third mutually orthogonal directions X, Y, and Z. As best shown in FIG. 1, the electronic device 100 includes opposite first and second sides 101 and 102 that are spaced apart from one another along the first direction X and extend along the second direction Y. The electronic device 100 also includes third and fourth sides 103 and 104 spaced apart from one another along the second direction Y, as well as a bottom side 105, and a top side 106 that is spaced apart from the bottom side 105 along the third direction Z. The electronic device 100 includes a molded or ceramic package structure 108 that includes the sides 101-106. In the illustrated example, the bottom and top sides 105 and 106 are generally planar and extend in respective X-Y planes of the first and second directions X and Y.

The electronic device 100 includes conductive leads 110 along the sides 101-104 to form a quad flat no-lead (QFN) package structure. In another implementation the device has conductive leads on two opposite sides to provide a DFN package structure (not shown). As best shown in FIG. 1B, the individual conductive leads 110 have a first surface 131 and a second surface 132. The first surface 131 in the example of FIG. 1B has a first plated layer 111 exposed outside the package structure 108 along the first side 101 of the package structure 108. The second surface 132 has a second plated layer 112 exposed outside the package structure 108 along the fifth side 105 (e.g., bottom) of the package structure 108. The conductive leads on the other lateral sides 102-104 of the electronic device 100 are similarly constructed. The second conductive leads 110 along the second side 102 have a first surface 131 and a second surface 132, where the first surface 131 has a first plated layer 111 exposed outside the package structure 108 along the second side 102 and the second surface 132 has a second plated layer 112 exposed outside of and along the fifth side 105 of the package structure 108. The third conductive leads 110 along the third side 103 and the fourth conductive leads 110 along the fourth side 104 also have first and second surfaces 131 and 132 as well as a first plated layer 111 along the respective lateral side and a second plated layer 112 exposed outside and along the fifth side 105 of the package structure 108. The electronic device 100 also includes a die attach pad 114 with a plated layer 115 like the first plated layer 111.

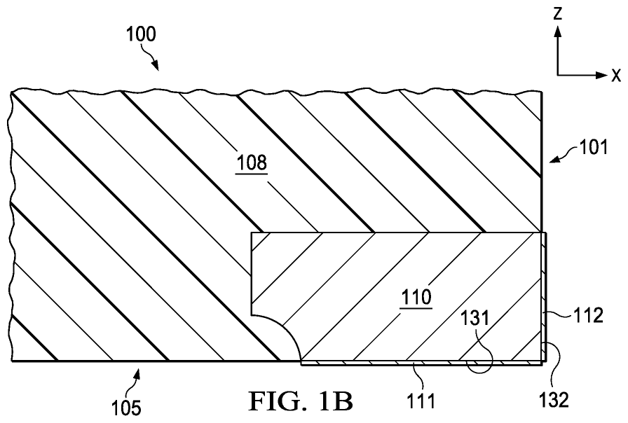

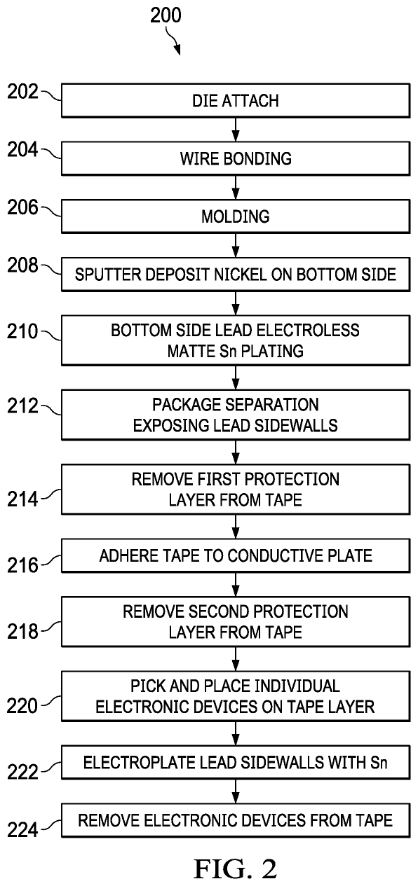

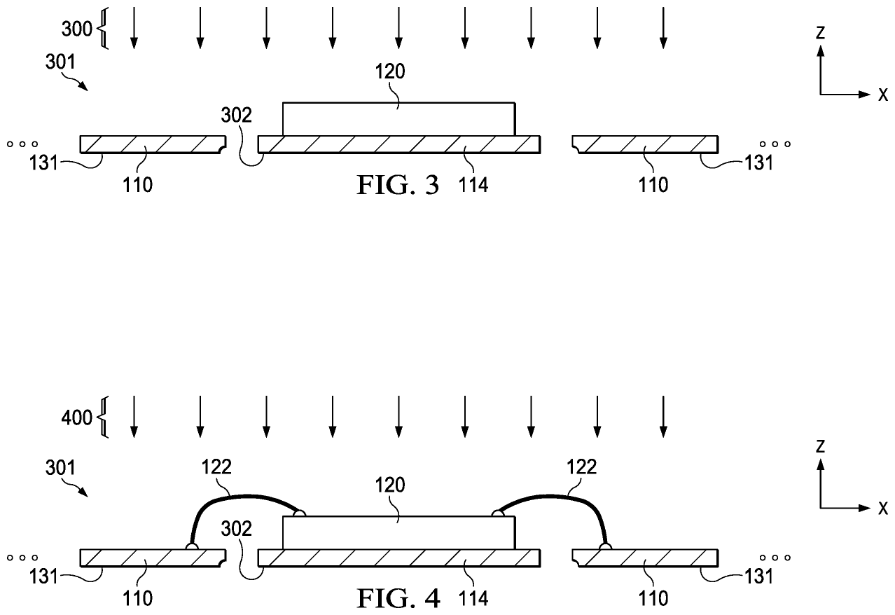

Referring also to FIGS. 2-14, FIG. 2 shows a method 200 of fabricating an electronic device and FIGS. 3-14 show the electronic device 100 undergoing fabrication processing according to the method 200. The method 200 includes die attach processing at 202. FIG. 3 shows one example, in which a die attach process 300 is performed that attaches the semiconductor die 120 to a die attach pad 114 of a starting lead frame that also includes the prospective leads 110. The die attach pad 114 has a lower surface 302 and the leads 110 have lower surfaces 131 as shown in FIG. 3. In one example, the starting lead frame has multiple prospective device sections arranged in a panel array 301 of rows and columns (not shown) of prospective electronic devices 100, and the die attach process 300 includes concurrent or sequential placement of multiple dies 120 to respective die attach pads 114 of the panel array 301.

The method 200 continues at 204 with electrical coupling including coupling one or more conductive terminals (e.g., bond pads) of the die 120 to respective conductive leads 110, as well as any die-to-die connections required for a given electronic device design (e.g., die-to-die connections for a multiple chip module or MCM device, not shown). FIG. 4 shows one example, in which a wire bonding process 400 is performed that forms bond wires 122 between respective conductive bond pads of the semiconductor die 120 and associated ones of the conductive leads 110 of the starting lead frame in the panel array 301. The method 200 also includes performing a molding process at 206 that forms a molded package structure 108 that encloses the semiconductor die 120 and the bond wires 122. FIG. 5 shows one example, in which a molding process 500 is performed that forms the molded package structure 108 that encloses the semiconductor die 120 and the bond wires 122.

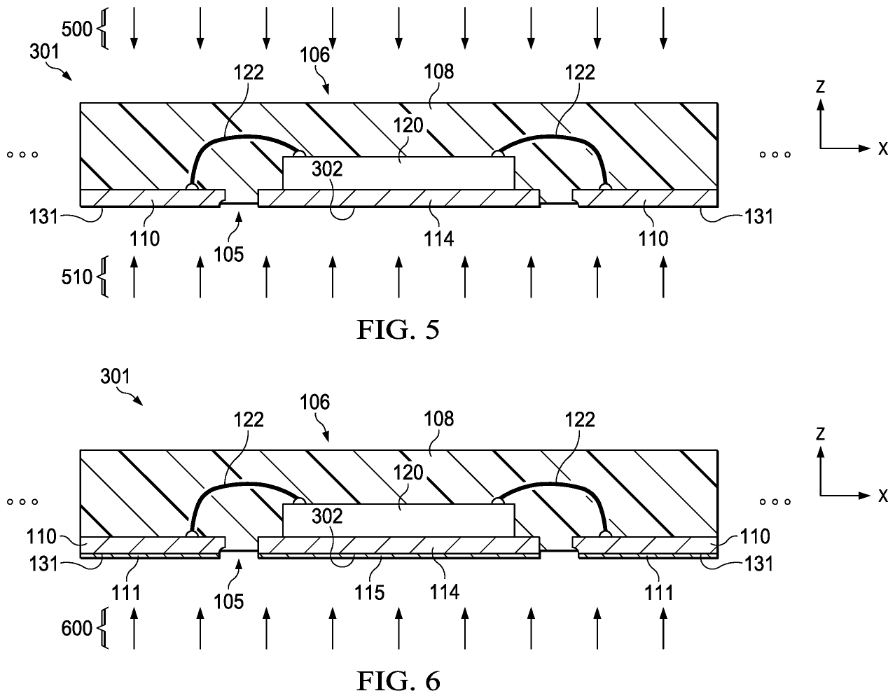

At 208, in one example, the method 200 includes depositing nickel on the bottom side 105 of the panel array 301. FIG. 5 shows one example, in which a sputter deposition process 510 is performed that deposits nickel on the bottom side 105 of the panel array 301 including forming nickel on the first surfaces 131 of the conductive leads 110 and on the bottom side 302 of the die attach pad 114. The method 200 also includes forming the first plated layer 111 at 210. FIG. 6 shows one example, in which a first plating process 600 is performed that forms the first plated layer 111 including tin (Sn) on the first surface 131 of the conductive leads 110 exposed along the bottom side 105 of the molded structure 108 in the panel array 301 of the prospective electronic devices. The first plating process 600 also forms the plated layer 115 including tin on the lower or bottom surface 302 of the die attach pad 114. In one implementation, the first plating process 600 is an electroless tin plating process that forms the first plated layer 111 including tin on the first surface 131 of the conductive lead 110 and forms the plated layer 115 including tin on the lower or bottom surface 302 of the die attach pad 114. In one example, the first plated layer 111, 115 is matt tin plating with a nominal thickness of 12 um.

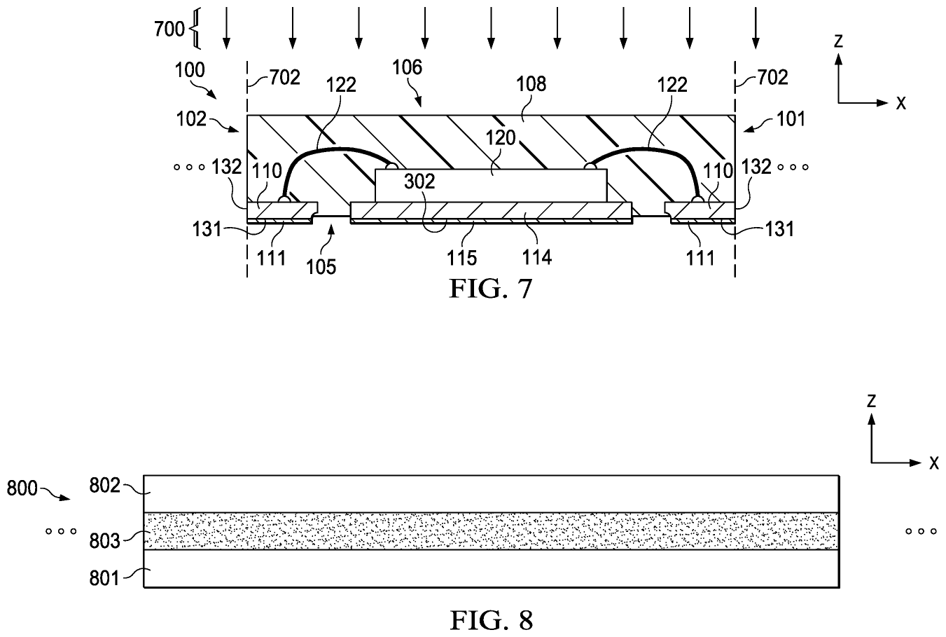

At 212 in FIG. 2, the method 200 includes package separation. FIG. 7 shows one example, in which a package separation process 700 is performed that separates an electronic device 100 from the panel array 301, for example, by saw cutting, laser cutting, or other suitable processing along lines 702. The separation process 700 separates the individual semiconductor device 100 with the tin-plated surface 131 of the conductive lead 110 exposed along the bottom side 105 of a respective package structure 108. The package separation process 700 exposes the second surface 132 of the illustrated conductive lead 110 along the first side 101 of the package structure 108, as well as the second surfaces 132 of the conductive leads 110 along the other lateral sides 102-104 (not shown). In the illustrated example, the exposed second surface 132 extends generally orthogonal to the bottom fifth side 105 of the separated package structure 108 (e.g., in a Y-Z plane of the second and third directions Y and Z in the illustrated orientation).

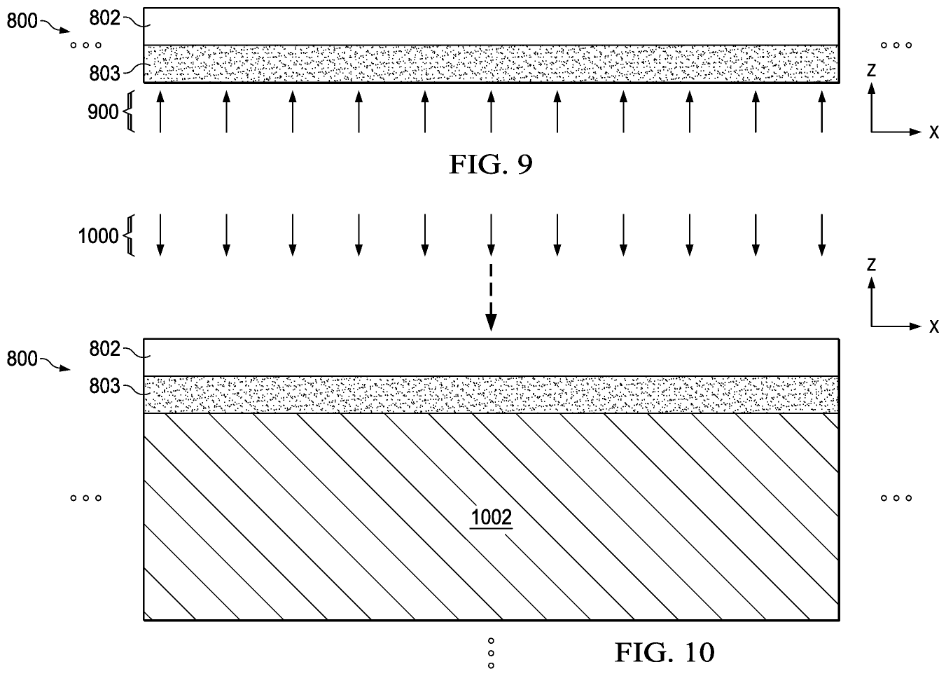

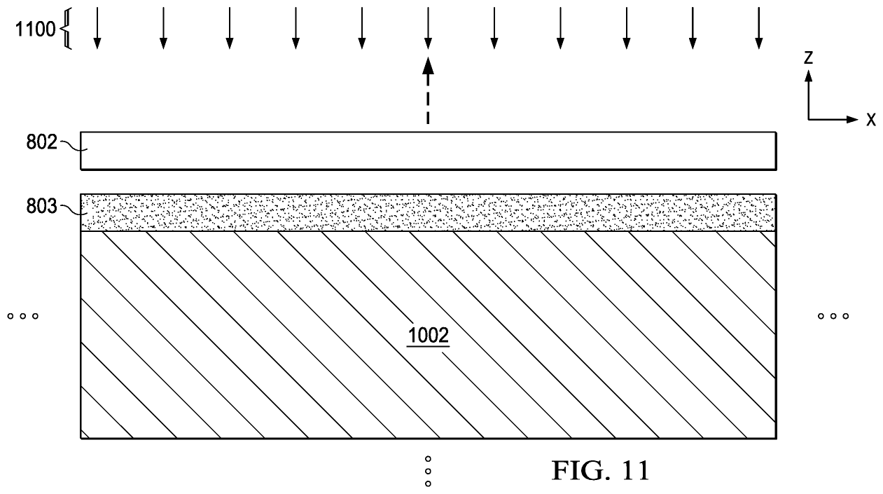

A tape structure and conductive plate are prepared at 214-218 in FIG. 2 for electroplating the second surfaces 132 of the conductive leads 110 to provide wettable flank protection. FIG. 8 shows a three-layer two-sided tape structure 800 with first and second removable protective layers 801 and 802 respectively below and above a two-sided adhesive tape layer 803. At 214, the first protective layer 801 is removed by a manual or automated removal process 900 shown in FIG. 9. At 216, the lower adhesive side of the two-sided adhesive tape layer 803 is adhered to a conductive plate. FIG. 10 shows one example, in which a manual or automated attachment process 1000 is performed that adheres the lower adhesive side of the two-sided adhesive tape layer 803 to an upper side of a conductive copper plate 1002. The top or second protective layer is then removed at 218. FIG. 11 shows one example, in which a manual or automated removal process 1100 is performed that removes the second protective layer 802 to expose the upper adhesive side of the two-sided adhesive tape layer 803. In one example, the tape layer 803 is chemically inert to plating chemistry. In this or other examples, the tape layer 803 is electrically conductive.

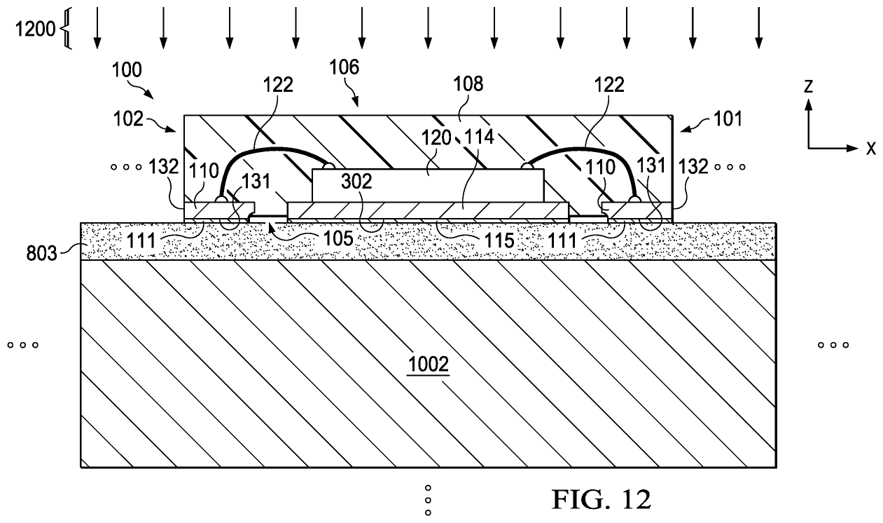

At 220 in FIG. 2, the bottom side 105 of the package structure 108 and the first plated layer 111 are placed on the adhesive top side of the tape layer 803 by an attachment process 1200 shown in FIG. 12. In one example, the attachment process 1200 is an automated pick and place process that adheres the bottom side 105 of the package structure 108 and the first plated layer 111 on the adhesive top side of the tape layer 803 above the conductive plate 1002. In this position, the bottom side 105 of the package structure 108 and the first plated layer 111 are in contact with the adhesive tape layer 803 and are not exposed to the subsequent electroplating operation that forms the second plated layer 112.

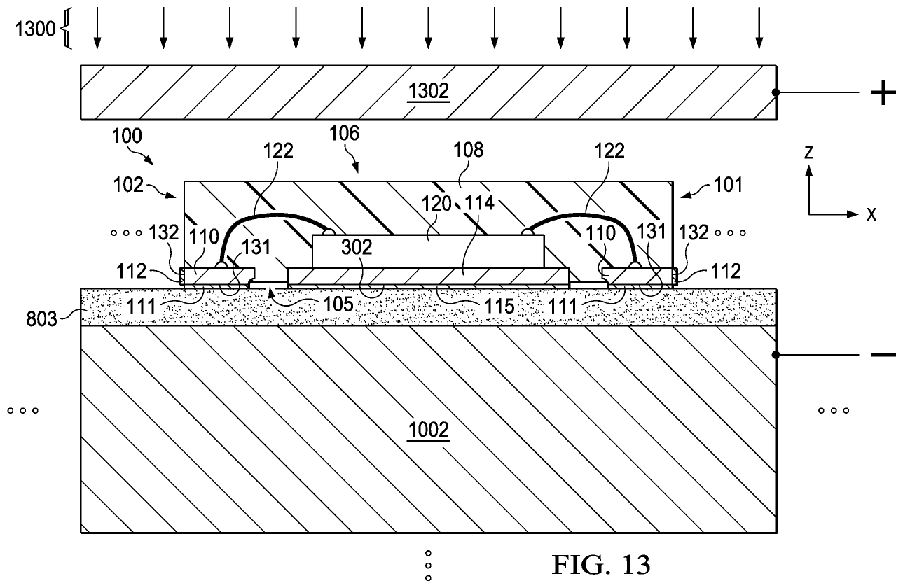

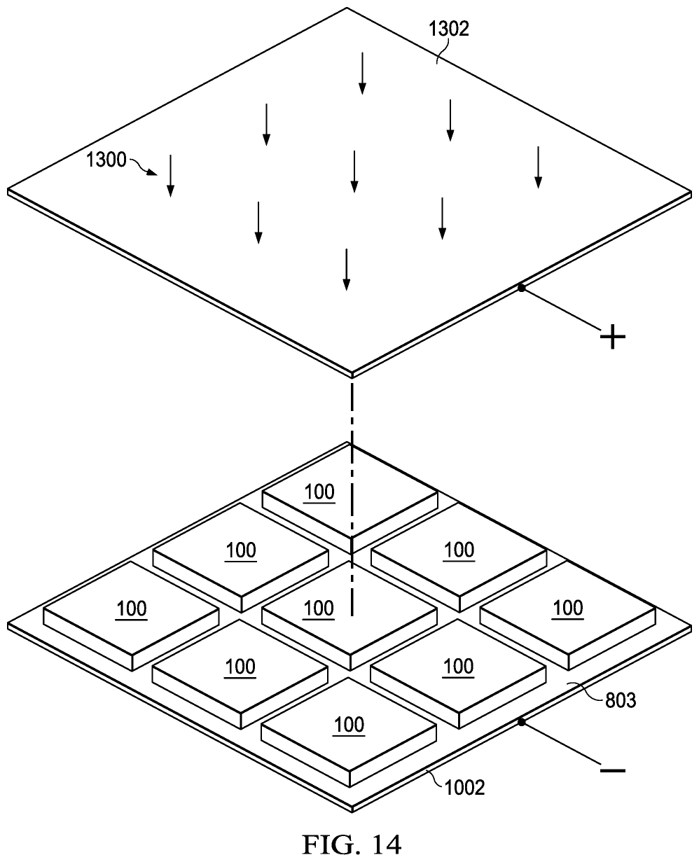

At 222, an electroplating is performed. FIGS. 13 and 14 show one example in which a second plating process 1300 is performed that forms the second plated layer 112 on the exposed second surfaces 132 of the conductive leads 110. In the illustrated example, the second plating process 1300 is a matt electroplating process performed with the conductive copper plate 1002 connected to a negative terminal of a plating supply (not shown), and the positive supply terminal is connected to an upper conductive (e.g., copper) plate 1302 that is spaced apart from and above the top side 106 of the electronic device 100. As shown in FIG. 14, the second plating process 1300 in one example concurrently plates the second plated layer 112 including tin on the exposed second surfaces 132 of the conductive leads 110 of multiple electronic devices 100 in an array of rows and columns adhered to the tape layer 803. In one example, the second plated layer 112 is matt tin plating with a nominal thickness of 12 um. The plating process 1300 does not change or disturb the first plated layers 111, 115 as these are covered by the tape 803, and the second plated layer 112 provides tin wettable flanks to the lateral second surfaces 132 of the conductive leads 110. The electronic device 100 are then removed from the tape 803 at 224, for example, using automated pick and place techniques and equipment (not shown).

The method 200 and the electronic device 100 provide enhanced wettable flank solutions for sawn QFN and DFN packages compared with immersion tin (Sn) plating, dimple plating, and step cut alternatives, each of which has its own challenges and disadvantages. For example, limitation in the achievable immersion tin layer approach, the shelf life of the plated package is limited and not as long as matt tin plating. Dimple and step cut options are limited in applicability related to the package design and minimum lead frame thickness. The electronic device 100 and the method 200 enable the use of matt tin electroplating to fully tin matt plate the side wall surfaces 132 of the conductive leads 110. The exposed bare Cu edges will be electrically connected to the conductive tape and are plated and the sidewalls or edges of the conductive leads 110 of the singulated package will be fully solderable. The bottom of the package will not be plated since it is covered by the tape layer 803, where the tape adhesive preferably allows no solution to penetrate into the interface. The tape layer 803 is removed in one example after the second plating process and a new tape 800 is used for a subsequent batch of electronic devices 100. In one implementation, the described techniques enables side-wettable flanks to facilitate solder wetting height of 100 um or more to provide a wettable flank solution suitable for QFN and thin flip-chip on lead (FCOL) devices having 6 mm thick lead frames suitable for automotive or industrial applications with an extended shelf life of 20 years or more.

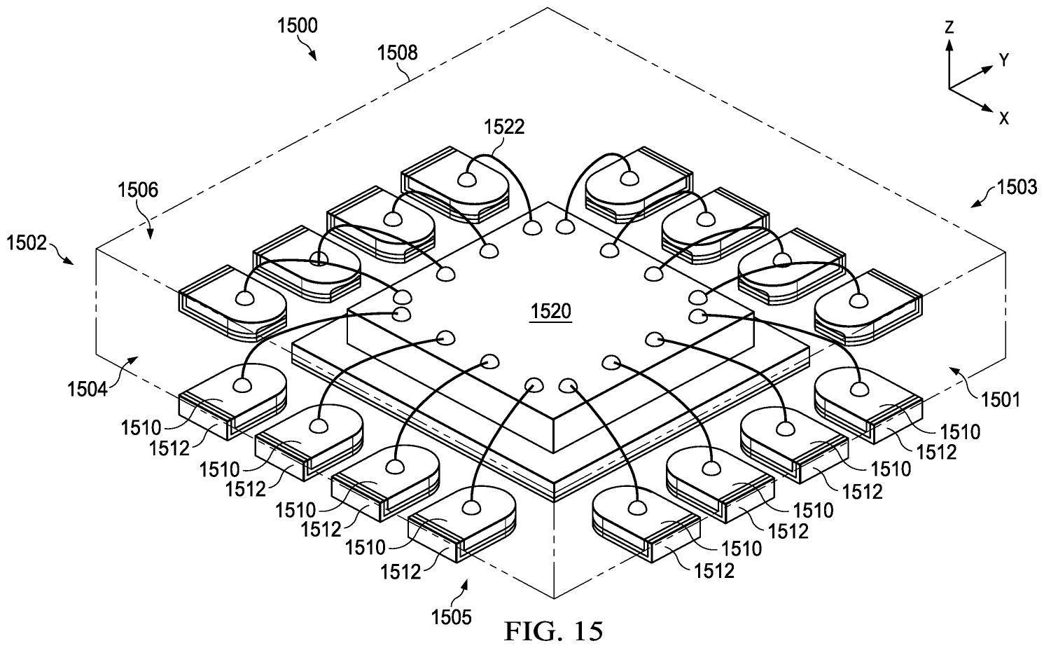

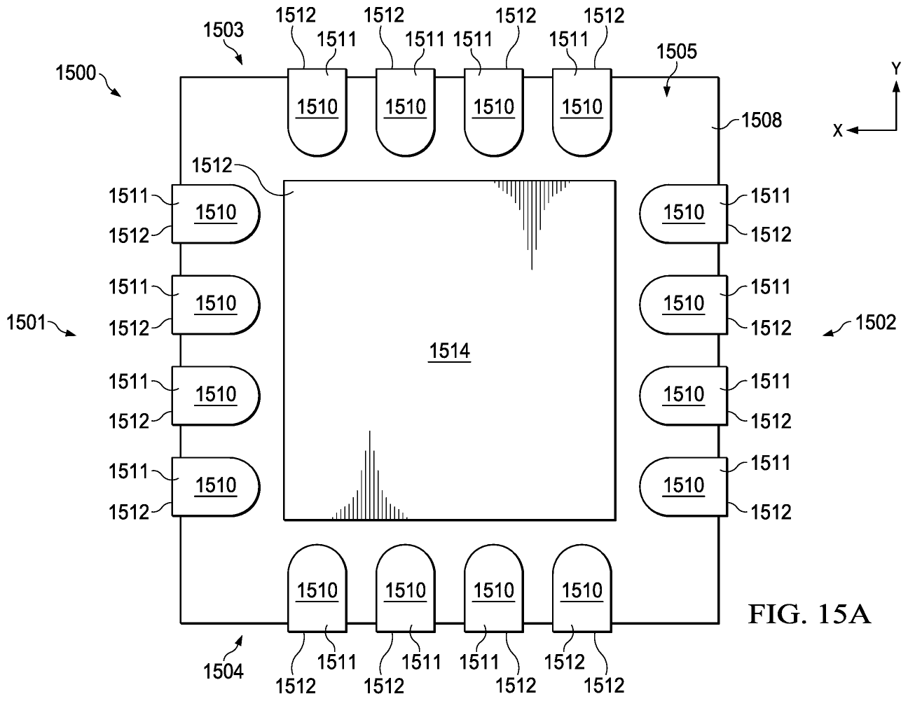

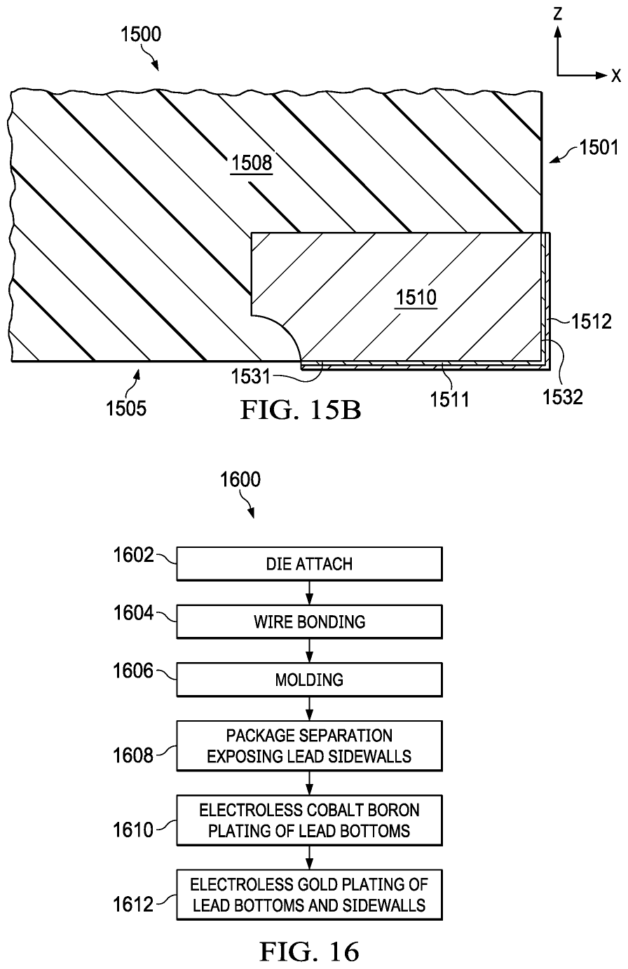

Referring now to FIGS. 15-15B, FIG. 15 shows a perspective view of another electronic device 1500, FIG. 15A shows a bottom view of the electronic device 1500 and FIG. 15B shows a partial sectional side elevation view of the electronic device 1500. The electronic device 1500 is illustrated in an example position in a three-dimensional space with respective first, second, and third mutually orthogonal directions X, Y, and Z. As best shown in FIG. 15, the electronic device 1500 includes opposite first and second sides 1501 and 1502 that are spaced apart from one another along the first direction X and extend along the second direction Y. The electronic device 1500 also includes third and fourth sides 1503 and 1504 spaced apart from one another along the second direction Y, as well as a bottom side 1505, and a top side 1506 that is spaced apart from the bottom side 1505 along the third direction Z. The electronic device 1500 includes a molded or ceramic package structure 1508 that includes the sides 1501-1506. In the illustrated example, the bottom and top sides 1505 and 1506 are generally planar and extend in respective X-Y planes of the first and second directions X and Y.

The electronic device 1500 includes conductive leads 1510 along the sides 1501-1504 to form a quad flat no-lead (QFN) package structure. In another implementation the device has conductive leads on two opposite sides to provide a DFN package structure (not shown). As best shown in FIG. 15B, the individual conductive leads 1510 have a first surface 1531 and a second surface 1532. The conductive leads 1510 in this example include a first plated layer 1511 that extends on the respective first and second surfaces 1531 and 1532 of the conductive lead 1510 and the first plated layer 1511 includes cobalt boride. The conductive leads 110 also have a second plated layer 1512 that extends on the first plated layer 1511 and includes gold. As shown in FIG. 15B, the second plated layer 1512 is exposed outside the package structure 1508 along the first side 1501 of the package structure 1508 and the second plated layer 1512 is exposed outside the package structure 1508 along the fifth side 1505 (e.g., bottom) of the package structure 1508.

The conductive leads on the other lateral sides 1502-1504 of the electronic device 1500 are similarly constructed. The second conductive leads 1510 along the second side 1502 have a first surface 1531 and a second surface 1532, as well as a first plated layer 1511 and a second plated layer 1512. The first surface 1531 of the second conductive lead 1510 extends along the second side 1502 of the package structure 1508, and the second surface 1532 of the second conductive lead 1510 extends along the fifth side 1505 of the package structure 1508. The first plated layer 1511 of the second conductive lead 1510 extends on the respective first and second surfaces 1531 and 1532 of the second conductive lead 1510 and includes cobalt boride. The second plated layer 1512 of the second conductive lead 1510 extends on the first plated layer 1511 of the second conductive lead 1510 and includes gold. The third conductive leads 1510 along the third side 1503 have a first surface 1531, a second surface 1532, a first plated layer 1511, and a second plated layer 1512. The first surface 1531 of the third conductive lead 1510 extends along the third side 1503 of the package structure 1508, and the second surface 1532 of the third conductive lead 1510 extends along the fifth side 1505 of the package structure 1508. The first plated layer 1511 of the third conductive lead 1510 extends on the first and second surfaces 1531, 1532 of the third conductive lead 1510 and includes cobalt boride. The second plated layer 1512 of the third conductive lead 1510 extends on the first plated layer 1511 of the third conductive lead 1510 and includes gold. The fourth conductive leads 1510 along the fourth side 1504 have a first surface 1531, a second surface 1532, a first plated layer 1511, and a second plated layer 1512. The first surface 1531 of the fourth conductive lead 1510 extends along the fourth side 1504 of the package structure 1508, and the second surface 1532 of the fourth conductive lead 1510 extends along the fifth side 1505 of the package structure 1508. The first plated layer 1511 of the fourth conductive lead 1510 extends on the first and second surfaces 1531, 1532 of the fourth conductive lead 1510 and includes cobalt boride. The second plated layer 1512 of the fourth conductive lead 1510 extends on the first plated layer 1511 of the fourth conductive lead 1510 and includes gold.

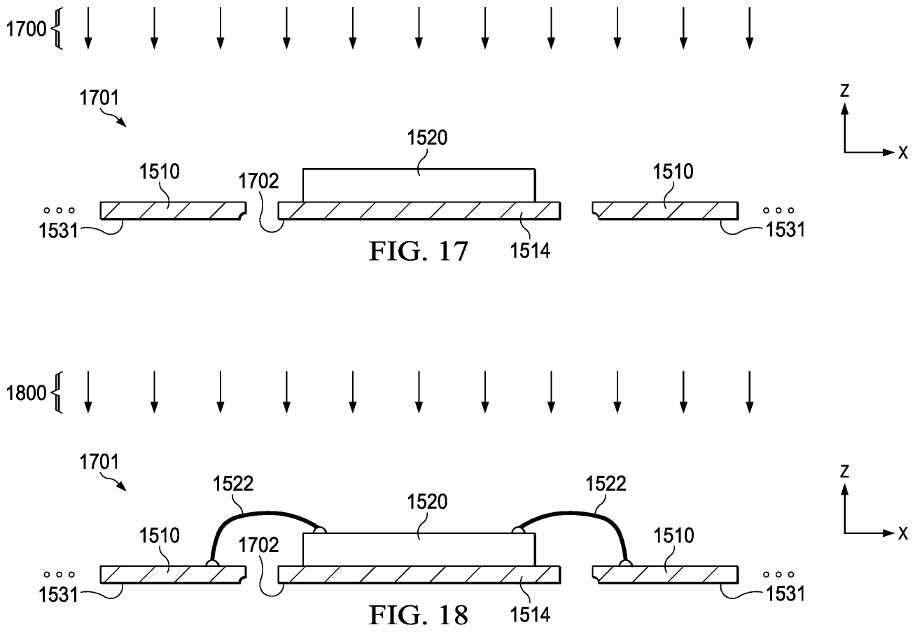

Referring also to FIGS. 16-23, FIG. 16 shows a method 1600 of fabricating an electronic device, and FIGS. 17-22 show the electronic device 1500 undergoing fabrication processing according to the method 1600. The method 1600 includes die attach processing at 1602. FIG. 17 shows one example, in which a die attach process 1700 is performed that attaches the semiconductor die 1520 to a die attach pad 1514 of a starting lead frame that also includes the prospective leads 1510. The die attach pad 1514 has a lower surface 1702 and the leads 1510 have lower surfaces 1531 as shown in FIG. 17. In one example, the starting lead frame has multiple prospective device sections arranged in a panel array 1701 of rows and columns (not shown) of prospective electronic devices 1500, and the die attach process 1700 includes concurrent or sequential placement of multiple dies 1520 to respective die attach pads 1514 of the panel array 1701.

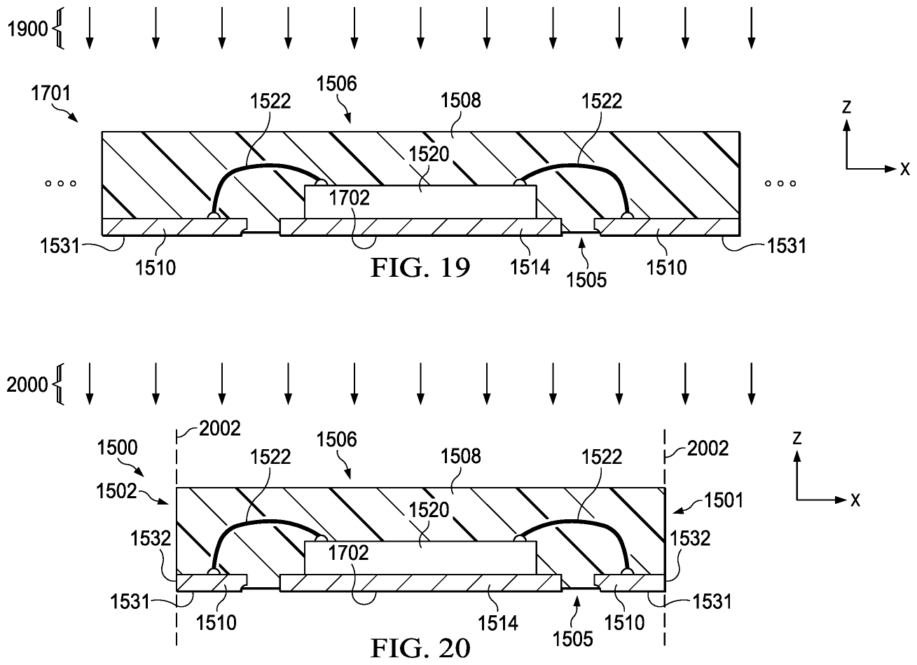

The method 1600 continues at 1604 with electrical coupling including coupling one or more conductive terminals (e.g., bond pads) of the die 1520 to respective conductive leads 1510, as well as any die-to-die connections required for a given electronic device design (e.g., die-to-die connections for a multiple chip module or MCM device, not shown). FIG. 18 shows one example, in which a wire bonding process 1800 is performed that forms bond wires 1522 between respective conductive bond pads of the semiconductor die 1520 and associated ones of the conductive leads 1510 of the starting lead frame in the panel array 1701. The method 1600 also includes performing a molding process at 1606 that forms a molded package structure 1508 that encloses the semiconductor die 1520 and the bond wires 1522. FIG. 19 shows one example, in which a molding process 1900 is performed that forms the molded package structure 1508 that encloses the semiconductor die 1520 and the bond wires 1522.

At 1608 in FIG. 16, the method 1600 includes package separation. FIG. 20 shows one example, in which a package separation process 2000 is performed that separates an electronic device 1500 from the panel array 1701, for example, by saw cutting, laser cutting, or other suitable processing along lines 2002. The separation process 2000 separates the individual semiconductor device 1500 with the first surface 1531 of the conductive lead 1510 exposed along the bottom side 1505 of a respective package structure 1508. The package separation process 2000 exposes the second surface 1532 of the illustrated conductive lead 1510 along the first side 1501 of the package structure 1508, as well as the second surfaces 1532 of the conductive leads 1510 along the other lateral sides 1502-1504 (not shown). In the illustrated example, the exposed second surface 1532 extends generally orthogonal to the bottom fifth side 1505 of the separated package structure 1508 (e.g., in a Y-Z plane of the second and third directions Y and Z in the illustrated orientation).

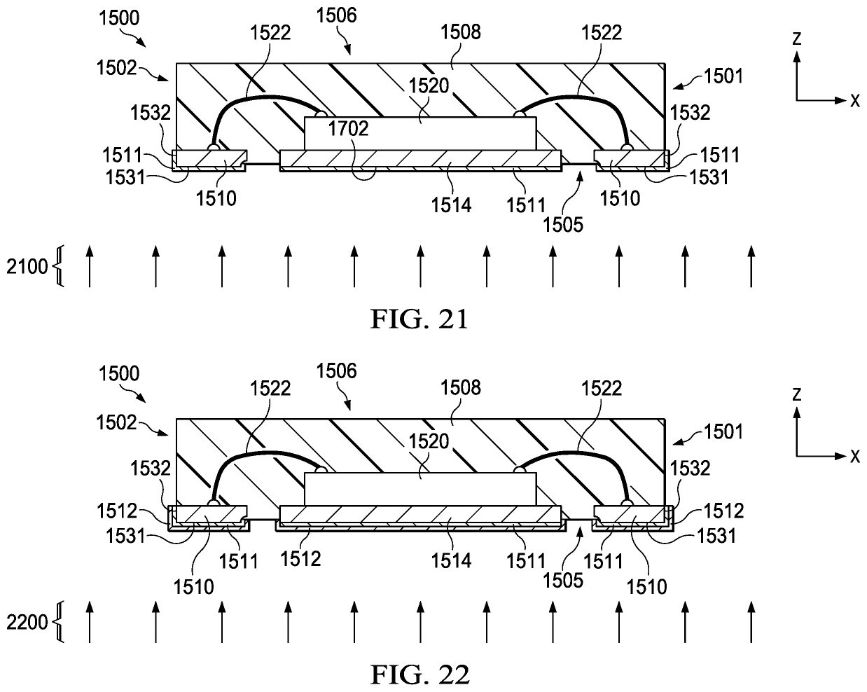

The method 1600 continues at 1610 with electroless cobalt boride plating. FIG. 21 shows one example, in which a first plating process 2100 is performed that forms the first plated layer 1511 including cobalt boride, which extends on the respective first and second surfaces 1531 and 1532 of the conductive leads 1510. In one example, the first plating process 2100 is an electroless plating process that forms the first plated layer 1511 including cobalt boride (e.g., CoxBy, such as CoB and Co₂B or other suitable stoichiometry) on the first and second surfaces 1531 and 1532 of the conductive leads 1510. The method 1600 continues at 1612 with electroless gold plating. FIG. 22 shows one example, in which a second plating process 2200 is performed that forms a second plated layer 1512 including gold and extending on the first plated layer 1511. In one example, the second plating process 1200 is an electroless process that forms the second plated layer 112 including gold on the exposed second surface 132 of the conductive lead 110.

The electroless plating of the cobalt boride first plated layer 1511 mitigates defects and provides larger grain sizes to operate as an effective diffusion barrier layer against interdiffusion of copper and tin. The barrier effect mitigates formation of intermetallic compounds (IMCs) such as Cu₃Sn and Cu₆Sn₅ and enhances board level reliability (BLR) performance since cobalt and copper have very low solubility in each other. The cobalt-tin intermetallic has high fracture toughness and high ductility resulting in solder voiding at the interface and avoiding cracking at the interface of Co—Cu IMC-matt Sn. The edge of the singulated packaged electronic device 1500 is fully solderable and provides a wettable flank QFN or DFN package.

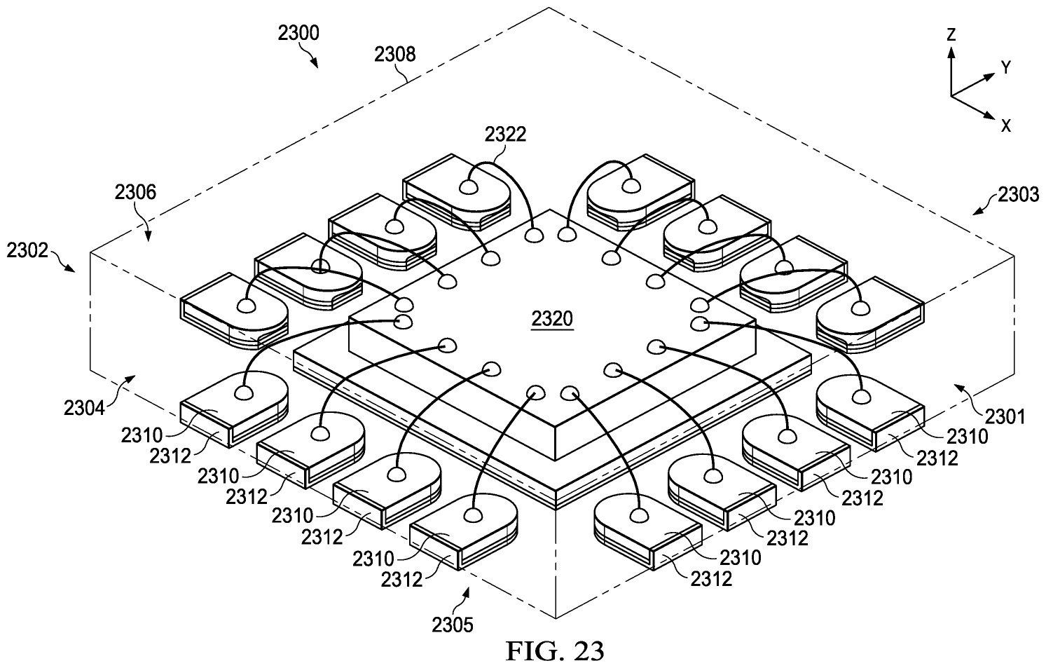

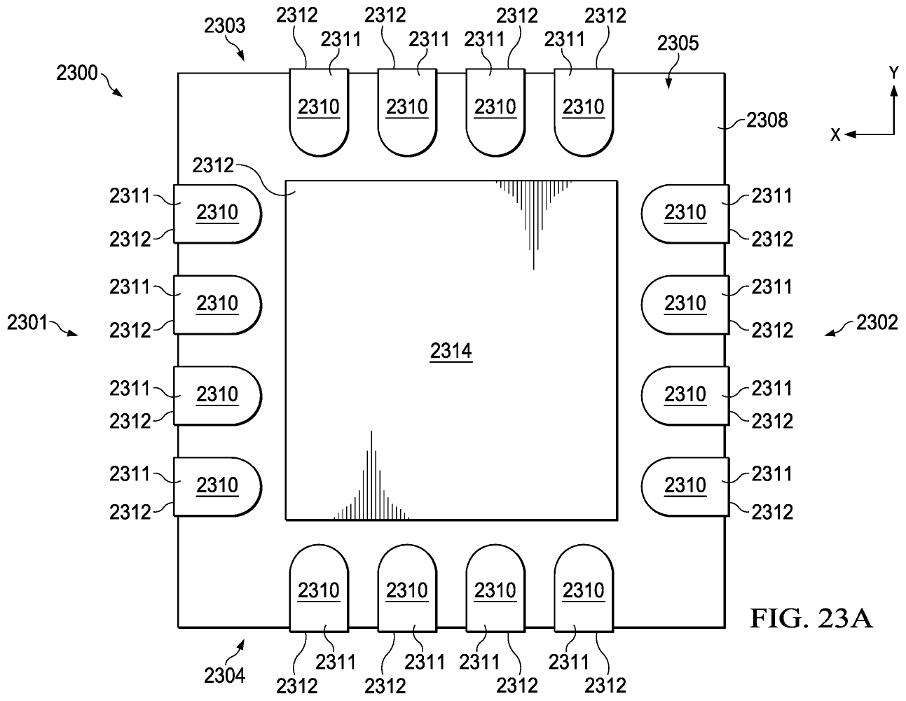

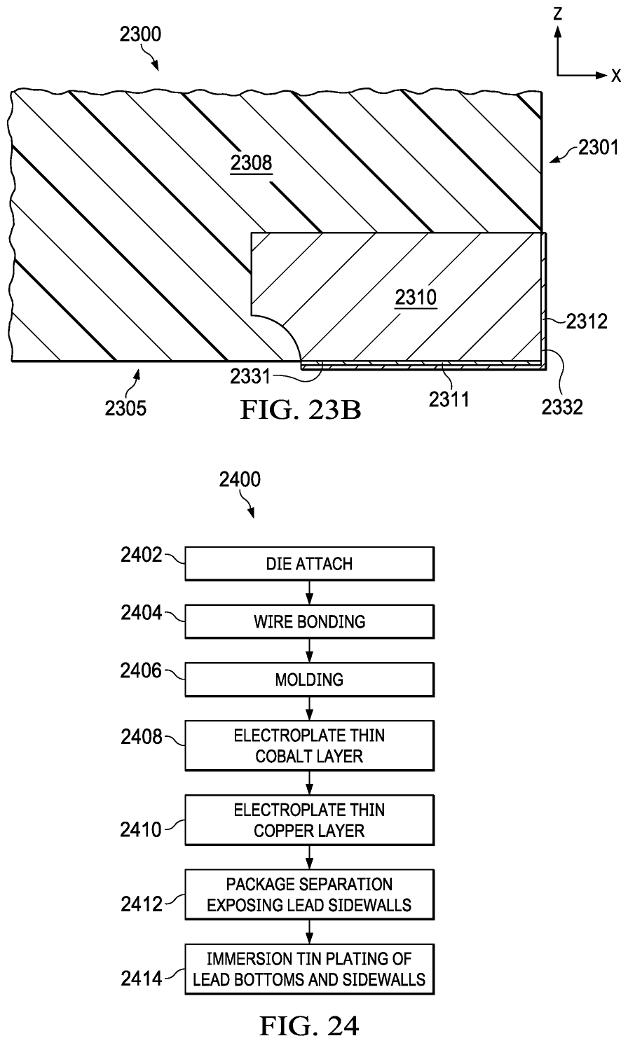

Referring now to FIGS. 23-23B, FIG. 23 shows a perspective view of another electronic device 2300, FIG. 23A shows a bottom view of the electronic device 2300 and FIG. 23B shows a partial sectional side elevation view of the electronic device 2300. The electronic device 2300 is illustrated in an example position in a three-dimensional space with respective first, second, and third mutually orthogonal directions X, Y, and Z. As best shown in FIG. 23, the electronic device 2300 includes opposite first and second sides 2301 and 2302 that are spaced apart from one another along the first direction X and extend along the second direction Y. The electronic device 2300 also includes third and fourth sides 2303 and 2304 spaced apart from one another along the second direction Y, as well as a bottom side 2305, and a top side 2306 that is spaced apart from the bottom side 2305 along the third direction Z. The electronic device 2300 includes a molded or ceramic package structure 2308 that includes the sides 2301-2306. In the illustrated example, the bottom and top sides 2305 and 2306 are generally planar and extend in respective X-Y planes of the first and second directions X and Y.

The electronic device 2300 includes conductive leads 2310 along the sides 2301-2304 to form a quad flat no-lead (QFN) package structure. In another implementation the device has conductive leads on two opposite sides to provide a DFN package structure (not shown). As best shown in FIG. 23B, the individual conductive leads 2310 have a first surface 2331 and a second surface 2332. The conductive leads 2310 in this example include a first plated layer 2311 that extends on the first surface 2331 of the conductive lead 2310 and the first plated layer 2311 includes cobalt. The conductive leads 110 also have a second plated layer 2312 that extends on the first plated layer 2311 and on the second surface 2332 of the conductive lead 2310. The second plated layer 2312 includes tin. As shown in FIG. 23B, the second plated layer 2312 is exposed outside the package structure 2308 along the first side 2301 of the package structure 2308 and the second plated layer 2312 is exposed outside the package structure 2308 along the fifth side 2305 (e.g., bottom) of the package structure 2308.

The conductive leads on the other lateral sides 2302-2304 of the electronic device 2300 are similarly constructed. The second conductive leads 2310 along the second side 2302 have a first surface 2331, a second surface 2332, a first plated layer 2311, and a second plated layer 2312. The first surface 2331 of the second conductive lead 2310 extends along the second side 2302 of the package structure 2308, and the second surface 2332 of the second conductive lead 2310 extends along the fifth side 2305 of the package structure 2308. The first plated layer 2311 of the second conductive lead 2310 extends on the first surface 2331 of the second conductive lead 2310 and includes cobalt. The second plated layer 2312 of the second conductive lead 2310 extends on the first plated layer 2311 of the second conductive lead 2310 and on the second surface 2332 of the second conductive lead 2310. The second plated layer 2312 of the second conductive lead 2310 includes tin. The third conductive leads 2310 along the third side 2303 have a first surface 2331, a second surface 2332, a first plated layer 2311, and a second plated layer 2312. For each conductive lead 2310 along the third side 2303, the first surface 2331 of the third conductive lead 2310 extends along the third side 2303 of the package structure 2308, and the second surface 2332 of the third conductive lead 2310 extends along the fifth side 2305 of the package structure 2308. The first plated layer 2311 of the third conductive lead 2310 extends on the first surface 2331 of the third conductive lead 2310 and includes cobalt. The second plated layer 2312 of the third conductive lead 2310 extends on the first plated layer 2311 of the third conductive lead 2310 and on the second surface 2332 of the third conductive lead 2310. The second plated layer 2312 of the third conductive lead 2310 includes tin. The fourth conductive leads 2310 along the fourth side 2304 include a first surface 2331, a second surface 2332, a first plated layer 2311, and a second plated layer 2312. For each, the first surface 2331 of the fourth conductive lead 2310 extends along the fourth side 2304 of the package structure 2308, and the second surface 2332 of the fourth conductive lead 2310 extends along the fifth side 2305 of the package structure 2308. The first plated layer 2311 of the fourth conductive lead 2310 extends on the first surface 2331 of the fourth conductive lead 2310 and includes cobalt. The second plated layer 2312 of the fourth conductive lead 2310 extends on the first plated layer 2311 of the fourth conductive lead 2310 and on the second surface 2332 of the fourth conductive lead 2310. The second plated layer 2312 of the fourth conductive lead 2310 includes tin.

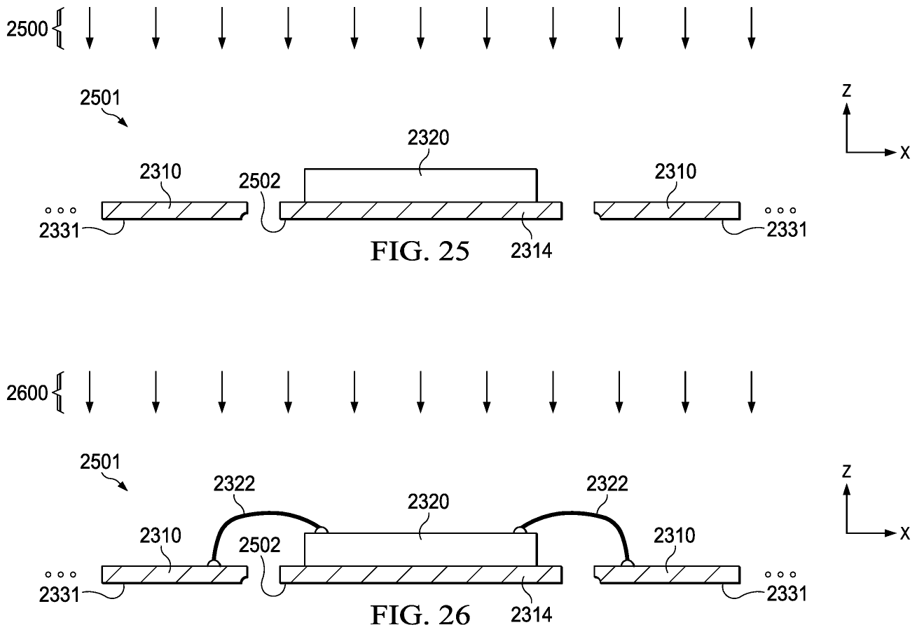

Referring also to FIGS. 24-31, FIG. 24 shows a method 2400 of fabricating an electronic device, and FIGS. 26-32 show the electronic device 2300 undergoing fabrication processing according to the method 2400. The method 2400 includes die attach processing at 2402. FIG. 26 shows one example, in which a die attach process 2600 is performed that attaches the semiconductor die 2320 to a die attach pad 2314 of a starting lead frame that also includes the prospective leads 2310. The die attach pad 2314 has a lower surface 2602 and the leads 2310 have lower surfaces 2331 as shown in FIG. 26. In one example, the starting lead frame has multiple prospective device sections arranged in a panel array 2601 of rows and columns (not shown) of prospective electronic devices 2300, and the die attach process 2600 includes concurrent or sequential placement of multiple dies 2320 to respective die attach pads 2314 of the panel array 2601.

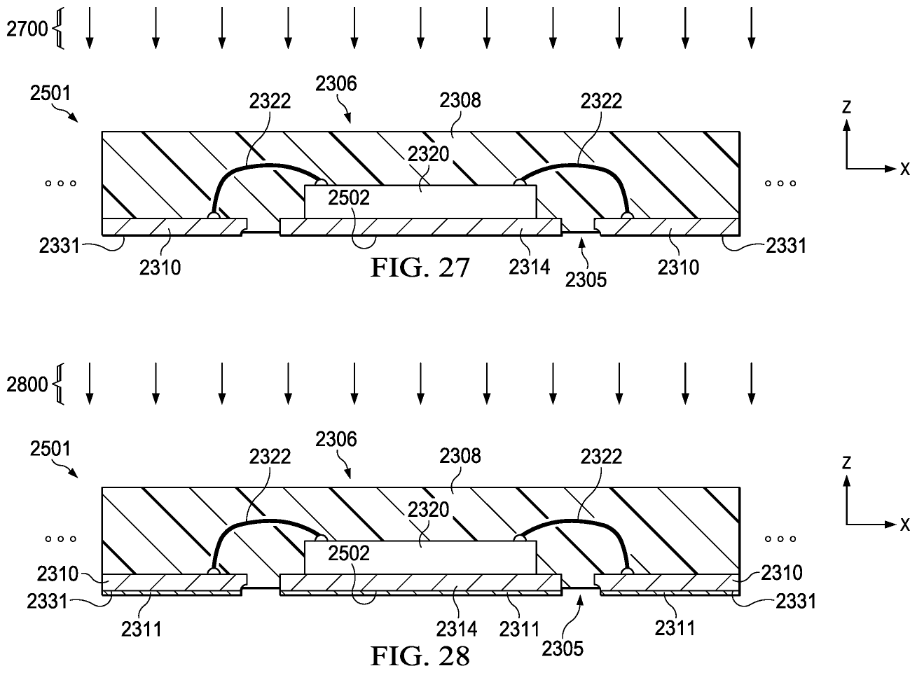

The method 2400 continues at 2404 with electrical coupling including coupling one or more conductive terminals (e.g., bond pads) of the die 2320 to respective conductive leads 2310, as well as any die-to-die connections required for a given electronic device design (e.g., die-to-die connections for a multiple chip module or MCM device, not shown). FIG. 26 shows one example, in which a wire bonding process 2600 is performed that forms bond wires 2322 between respective conductive bond pads of the semiconductor die 2320 and associated ones of the conductive leads 2310 of the starting lead frame in the panel array 2601. The method 2400 also includes performing a molding process at 2406 that forms a molded package structure 2308 that encloses the semiconductor die 2320 and the bond wires 2322. FIG. 27 shows one example, in which a molding process 2700 is performed that forms the molded package structure 2308 that encloses the semiconductor die 2320 and the bond wires 2322.

The method 2400 continues at 2408 with a first electroplating process using cobalt. FIG. 28 shows one example, in which an electroplating process 2800 is performed that forms the first plated layer 2311 including cobalt on the first surface 2331 of the conductive lead 2310 exposed along the bottom side 2305 of the molded structure 2308 in the panel array 2601 of the prospective electronic devices 2300. In one example, the first plating process 2800 is an electroplating process that forms the first plated layer 2311 including cobalt to a thickness of approximately 1 μm or more and approximately 3 μm or less on the first surface 2331 of the conductive lead 2310 exposed along the bottom side 2305 of the molded structure 2308 in the panel array 2601.

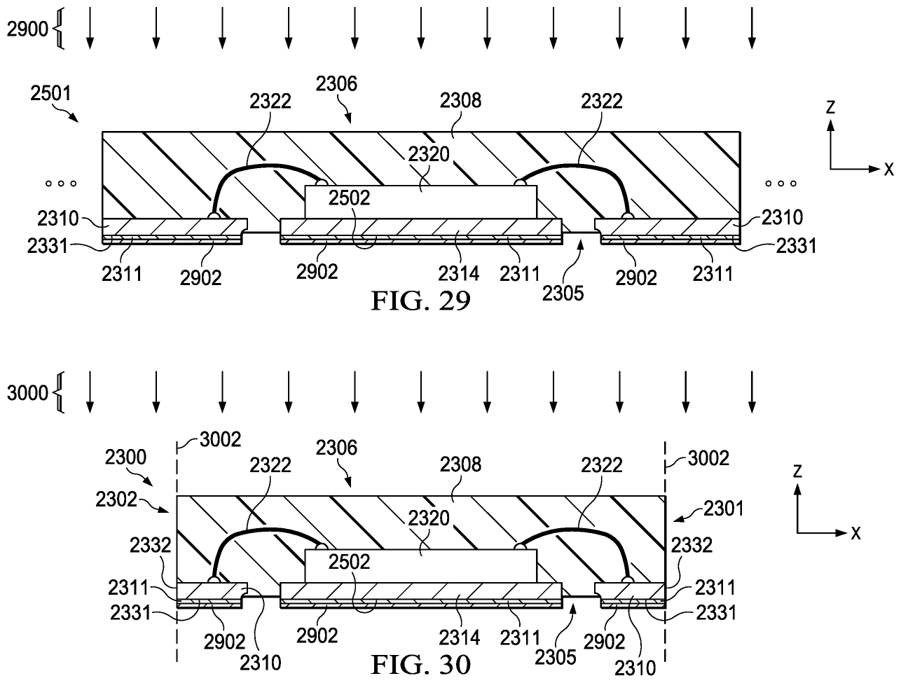

A second electroplating process is performed at 2410 to form a copper layer on the first plated layer 2311. FIG. 29 shows one example, in which a second electroplating process 2900 is performed that forms a thin copper layer 2902 on the first plated layer 2311. In one example, the second plating process 2900 is an electroplating process that forms the copper layer 2902 to a thickness of approximately 15 nm or more and approximately 2.0 μm or less on the first plated layer 2311.

The method 2400 continues at 2412 with package separation. FIG. 30 shows one example, in which a package separation process 3000 is performed that separates an electronic device 2300 from the panel array 2601, for example, by saw cutting, laser cutting, or other suitable processing along lines 3002. The separation process 3000 separates the individual semiconductor device 2300 with the first surface 2331 of the conductive lead 2310 exposed along the bottom side 2305 of a respective package structure 2308. The package separation process 3000 exposes the second surface 2332 of the illustrated conductive lead 2310 along the first side 2301 of the package structure 2308, as well as the second surfaces 2332 of the conductive leads 2310 along the other lateral sides 2302-2304 (not shown). In the illustrated example, the exposed second surface 2332 extends generally orthogonal to the bottom fifth side 2305 of the separated package structure 2308 (e.g., in a Y-Z plane of the second and third directions Y and Z in the illustrated orientation).

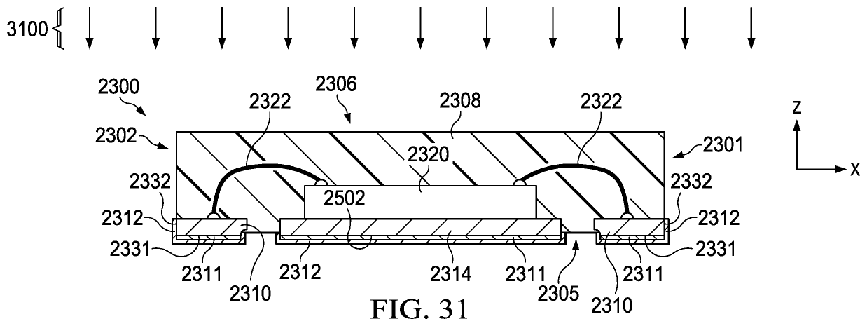

A third plating process is performed at 2414. FIG. 31 shows one example, in which an immersion plating process 3100 is performed that forms the second plated layer 2312 including tin on the second surface 2332 of the conductive lead 2310 along a first side 2301 of the package structure 2308. The immersion plating process 3100 consumes all or at least a portion of the copper layer 2902 to form the second plated layer 2312 including tin on the first plated layer 2311 of the first surface 2331 of the conductive lead 2310.

The cobalt plating of the first plated layer 2311 mitigates defects and provides larger grain sizes to operate as an effective diffusion barrier layer against interdiffusion of copper and tin due to the fact that Co and Cu have minimal solid solution solubility. The barrier effect mitigates formation of intermetallic compounds (IMCs) such as Cu₃Sn and Cu₆Sn₅ and enhances board level reliability (BLR) performance since cobalt and copper have very low solubility in each other. The cobalt-tin intermetallic has high fracture toughness and high ductility resulting in solder voiding at the interface and avoiding cracking at the interface of Co—Cu IMC-matt Sn. The edge of the singulated packaged electronic device 1500 is fully solderable and provides a wettable flank QFN or DFN package. The electronic device 2300 and the method 2400 provide an effective solution where a specific application requires both the sidewall or edge and the bottom of the package to be plated at the same time through the same plating process and plating materials. The described solution is advantageous compared with applying immersion tin plating on the edge (exposed bare copper) and bottom at the same time since applying immersion tin on the bottom leads to poor board level reliability performance due to the copper-tin interdiffusion and formation of large amount of IMCs. Providing the cobalt under layer provides an efficient diffusion barrier against copper and tin and improves BLR performance. The described examples, moreover, provide both the lead and the bottom of the package with the same finish through the process. In one example, the bottom of the package includes cobalt and immersion tin and the edge includes immersion tin. Since cobalt functions as an efficient diffusion barrier layer against interdiffusion of copper and tin, the BLR performance of the package is not sacrificed as a result of immersion tin plating on the bottom of the package.

The above examples are merely illustrative of several possible implementations of various aspects of the present disclosure, wherein equivalent alterations and/or modifications will occur to others skilled in the art upon reading and understanding this specification and the annexed drawings. Unless otherwise stated, “about,” “approximately,” or “substantially” preceding a value means+/−10 percent of the stated value. Modifications are possible in the described examples, and other implementations are possible, within the scope of the claims.

What is claimed is:

1. An electronic device, comprising:
a package structure having six sides, the six sides including opposite first and second sides spaced apart from one another along a first direction, opposite third and fourth sides spaced apart from one another along a second direction that is orthogonal to the first direction, and opposite fifth and sixth sides spaced apart from one another along a third direction that is orthogonal to the first and second directions; and
a conductive lead having a first surface and a second surface, the first surface having a first plated layer exposed outside the package structure along the first side of the package structure, and the second surface having a second plated layer exposed outside the package structure along the fifth side of the package structure.

2. The electronic device of claim 1, wherein the second plated layer includes tin.

3. The electronic device of claim 1, further comprising a second conductive lead having a first surface and a second surface, the first surface of the second conductive lead having a first plated layer exposed outside the package structure along the second side of the package structure, and the second surface of the second conductive lead having a second plated layer exposed outside the package structure along the fifth side of the package structure.

4. The electronic device of claim 3, further comprising:
a third conductive lead having a first surface and a second surface, the first surface of the third conductive lead having a first plated layer exposed outside the package structure along the third side of the package structure, and the second surface of the third conductive lead having a second plated layer exposed outside the package structure along the fifth side of the package structure; and
a fourth conductive lead having a first surface and a second surface, the first surface of the fourth conductive lead having a first plated layer exposed outside the package structure along the fourth side of the package structure, and the second surface of the fourth conductive lead having a second plated layer exposed outside the package structure along the fifth side of the package structure.

5. A method of fabricating an electronic device, the method comprising:
performing a first plating process that forms a first plated layer on a first surface of a conductive lead exposed along a bottom side of a molded structure in a panel array of prospective electronic devices;
performing a package separation process that separates an electronic device from the panel array, with the conductive lead exposed along the bottom side of a respective package structure, and exposes a second surface of the conductive lead along a first side of the package structure;
placing the bottom side of the package structure and the first plated layer on a tape layer above a conductive plate; and
performing a second plating process that forms a second plated layer on the exposed second surface of the conductive lead.

6. The method of claim 5, wherein the second plating process is an electroplating process that forms the second plated layer including tin on the exposed second surface of the conductive lead.

7. The method of claim 5, wherein the first plating process is an electroless plating process that forms the first plated layer including tin on the first surface of the conductive lead.

8. An electronic device, comprising:
a package structure having six sides, the six sides including opposite first and second sides spaced apart from one another along a first direction, opposite third and fourth sides spaced apart from one another along a second direction that is orthogonal to the first direction, and opposite fifth and sixth sides spaced apart from one another along a third direction that is orthogonal to the first and second directions; and
a conductive lead having a first surface, a second surface, a first plated layer, and a second plated layer, the first surface extending along the first side of the package structure, and the second surface extending along the fifth side of the package structure, the first plated layer extending on the first and second surfaces of the conductive lead and including cobalt boride, and the second plated layer extending on the first plated layer and including gold.

9. The electronic device of claim 8, further comprising a second conductive lead having a first surface, a second surface, a first plated layer, and a second plated layer, the first surface of the second conductive lead extending along the second side of the package structure, and the second surface of the second conductive lead extending along the fifth side of the package structure, the first plated layer of the second conductive lead extending on the first and second surfaces of the second conductive lead and including cobalt boride, and the second plated layer of the second conductive lead extending on the first plated layer of the second conductive lead and including gold.

10. The electronic device of claim 9, further comprising:
a third conductive lead having a first surface, a second surface, a first plated layer, and a second plated layer, the first surface of the third conductive lead extending along the third side of the package structure, and the second surface of the third conductive lead extending along the fifth side of the package structure, the first plated layer of the third conductive lead extending on the first and second surfaces of the third conductive lead and including cobalt boride, and the second plated layer of the third conductive lead extending on the first plated layer of the third conductive lead and including gold; and
a fourth conductive lead having a first surface, a second surface, a first plated layer, and a second plated layer, the first surface of the fourth conductive lead extending along the fourth side of the package structure, and the second surface of the fourth conductive lead extending along the fifth side of the package structure, the first plated layer of the fourth conductive lead extending on the first and second surfaces of the fourth conductive lead and including cobalt boride, and the second plated layer of the fourth conductive lead extending on the first plated layer of the fourth conductive lead and including gold.

11. A method of fabricating an electronic device, the method comprising:
performing a package separation process that separates an electronic device from a panel array, with a first surface of a conductive lead exposed along a bottom side of a respective package structure, and exposes a second surface of the conductive lead along a first side of the package structure;
performing a first plating process that forms a first plated layer extending on the first and second surfaces of the conductive lead and including cobalt boride; and
performing a second plating process that forms a second plated layer extending on the first plated layer and including gold.

12. The method of claim 11, wherein the second plating process is an electroless process that forms the second plated layer including gold on the exposed second surface of the conductive lead.

13. The method of claim 11, wherein the first plating process is an electroless plating process that forms the first plated layer including cobalt boride on the first and second surfaces of the conductive lead.

14. An electronic device, comprising:
a package structure having six sides, the six sides including opposite first and second sides spaced apart from one another along a first direction, opposite third and fourth sides spaced apart from one another along a second direction that is orthogonal to the first direction, and opposite fifth and sixth sides spaced apart from one another along a third direction that is orthogonal to the first and second directions; and
a conductive lead having a first surface, a second surface, a first plated layer, and a second plated layer, the first surface extending along the first side of the package structure, and the second surface extending along the fifth side of the package structure, the first plated layer extending on the first surface of the conductive lead and including cobalt, the second plated layer extending on the first plated layer and on the second surface of the conductive lead, and the second plated layer including tin.

15. The electronic device of claim 14, further comprising a second conductive lead having a first surface, a second surface, a first plated layer, and a second plated layer, the first surface of the second conductive lead extending along the second side of the package structure, and the second surface of the second conductive lead extending along the fifth side of the package structure, the first plated layer of the second conductive lead extending on the first surface of the second conductive lead and including cobalt, and the second plated layer of the second conductive lead extending on the first plated layer of the second conductive lead and on the second surface of the second conductive lead, and the second plated layer of the second conductive lead including tin.

16. The electronic device of claim 15, further comprising:
a third conductive lead having a first surface, a second surface, a first plated layer, and a second plated layer, the first surface of the third conductive lead extending along the third side of the package structure, and the second surface of the third conductive lead extending along the fifth side of the package structure, the first plated layer of the third conductive lead extending on the first surface of the third conductive lead and including cobalt, and the second plated layer of the third conductive lead extending on the first plated layer of the third conductive lead and on the second surface of the third conductive lead, and the second plated layer of the third conductive lead including tin; and
a fourth conductive lead having a first surface, a second surface, a first plated layer, and a second plated layer, the first surface of the fourth conductive lead extending along the fourth side of the package structure, and the second surface of the fourth conductive lead extending along the fifth side of the package structure, the first plated layer of the fourth conductive lead extending on the first surface of the fourth conductive lead and including cobalt, and the second plated layer of the fourth conductive lead extending on the first plated layer of the fourth conductive lead and on the second surface of the fourth conductive lead, and the second plated layer of the fourth conductive lead including tin.

17. A method of fabricating an electronic device, the method comprising:
performing a first plating process that forms a first plated layer on a first surface of a conductive lead exposed along a bottom side of a molded structure in a panel array of prospective electronic devices, the first plated layer including cobalt;
performing a second plating process that forms a copper layer on the first plated layer;
performing a package separation process that separates an electronic device from the panel array, with the conductive lead exposed along the bottom side of a respective package structure, and exposes a second surface of the conductive lead along a first side of the package structure; and
performing a third plating process that forms a second plated layer including tin on the second surface of the conductive lead along a first side of the package structure and consumes the copper layer to form the second plated layer including tin on the first plated layer of the first surface of the conductive lead.

18. The method of claim 17, wherein the first plating process is an electroplating process that forms the first plated layer including cobalt to a thickness of approximately 1 μm or more and approximately 3 μm or less.

19. The method of claim 18, wherein the second plating process is an electroplating process that forms the copper layer to a thickness of approximately 15 nm or more and approximately 2.0 μm or less.

20. The method of claim 18, wherein the third plating process is an immersion plating process.
